(19) United States
(12) Patent Application Publication
(10) Pub. No.: US 2025/0079205 A1
(43) Pub. Date: Mar. 6, 2025

(54) EQUIPMENT FRONT-END MODULE AND SUBSTRATE PROCESSING APPARATUS INCLUDING THE SAME

(71) Applicant: Samsung Electronics Co., Ltd., Suwon-si (KR)

(72) Inventors: Pyeong Gyu SONG, Suwon-si (KR); Sung MIn Kim, Suwon-si (KR); Moo Young Lim, Suwon-si (KR); Ji Yong Lee, Suwon-si (KR); Sung Girl Lim, Suwon-si (KR)

(73) Assignee: Samsung Electronics Co., Ltd., Suwon-si (KR)

(21) Appl. No.: 18/679,010

(22) Filed: May 30, 2024

(30) Foreign Application Priority Data
Sep. 5, 2023 (KR) 10-2023-0117634
Jan. 3, 2024 (KR) 10-2024-0000886

(51) Int. Cl. H01L 21/67

(52) U.S. Cl. CPC H01L 21/67201

(57) ABSTRACT

A equipment front-end module (EFEM) includes: a body part; load ports in the body part and having loaded therein front opening unified pods (FOUPs), where wafers are stored; doors in the body part, movable in a first direction, and opening and closing entrances of the load ports; a fan unit on the load ports and providing an airflow in a direction opposite of the first direction; a first screen plate between the fan unit and the load ports, attached to the body part, and including a slant edge, that extends in a second direction that intersects the first direction; and second screen plates attached to the doors and extending in the first direction from upper surfaces of the doors, wherein the first screen plate changes a direction of the airflow, and the second screen plates prevent the airflow from entering the load ports.

### CROSS-REFERENCE TO RELATED APPLICATIONS

This application claims priority to Korean Patent Application No. 10-2023-0117634, filed on Sep. 5, 2023, and Korean Application No. 10-2024-0000886, filed on Jan. 3, 2024, in the Korean Intellectual Property Office, the disclosures of which are incorporated by reference herein in their entireties.

### BACKGROUND

The present disclosure relates to an equipment front-end module and substrate processing apparatus including the same.

A wafer processing apparatus may include: an equipment front-end module (EFEM), which includes a load port where a wafer carrier is seated, a load lock, which temporarily houses wafers and where internal pressure is regulated, and an arm, which unloads wafers from the wafer carrier and introduces the wafers into the load lock; a wafer processing chamber where the wafers are processed; and a wafer transfer arm, which transports the wafers from within the EFEM to the wafer processing chamber.

Recently, there has been research aimed at improving wafer processing efficiency within process chambers where wafer processing apparatuses are installed.

### SUMMARY

One or more embodiments of the present disclosure provide an equipment front-end module (EFEM) with improved performance and reliability is provided.

Further, one or more embodiments of the present disclosure provide a substrate processing apparatus including an EFEM with improved performance and reliability is provided.

According to an aspect of an example embodiment, an EFEM includes: a body part; load ports in the body part and configured to have loaded therein front opening unified pods (FOUPs) that are configured to store a plurality of wafers; doors in the body part and configured to move in a first direction, and open and close entrances of the load ports; a fan unit on the load ports and configured to provide an airflow in a direction opposite to the first direction; a first screen plate between the fan unit and the load ports, attached to the body part, and including a slant edge that extends in a second direction that intersects the first direction; and second screen plates attached to the doors and that extend in the first direction from upper surfaces of the doors, wherein the first screen plate is configured to change a direction of the airflow, and wherein the second screen plates are configured to prevent the airflow from entering the load ports.

According to an aspect of an example embodiment, an EFEM includes: a body part; load ports in the body part and configured have loaded therein front opening unified pods (FOUPs) that are configured to store a plurality of wafers; doors in the body part and configured to move in a first direction, and open and close entrances of the load ports; a fan unit on the load ports and configured to provide an airflow in a direction opposite to the first direction; a first screen plate between the fan unit and the load ports, attached to the body part, and including a slant edge that extends in a second direction that intersects the first direction, a bottom surface that is connected to the slant edge and extends in a third direction that intersects the first direction and the second direction, and sidewalls that are connected to the slant edge and the bottom surface; second screen plates attached to the doors and extending in the first direction from upper surfaces of the doors; and an index robot configured to grasp and transfer the plurality of wafers disposed in the load ports, wherein an interior of the first screen plate defined by the slant edge, the bottom surface, and the sidewalls is an empty space, and wherein a height from lower surfaces of the load ports to a bottom surface of the first screen plate is greater than a height from the lower surfaces of the load ports to an uppermost part of the index robot.

According to an aspect of an example embodiment, substrate processing apparatus includes: an EFEM that is configured to accommodate front opening unified pods (FOUPs) that store wafers; a process chamber connected to the EFEM and configured to perform a semiconductor process on the wafers; and a cleaning chamber configured to perform a cleaning process on the wafers that have been subjected to the semiconductor process, wherein the EFEM includes: a body part; load ports that are in the body part and are configured to have the FOUPs loaded therein, doors in the body part and configured to move in a first direction, and open and close entrances of the load ports; a fan unit on the load ports and configured to provide an airflow in a direction opposite to the first direction, a first screen plate between the fan unit and the load ports, and attached to the body part, the first screen plate including a slant edge extending in a second direction that intersects the first direction, and second screen plates attached to the doors and extending in the first direction from upper surfaces of the doors, wherein the first screen plate is configured to change a direction of the airflow, and wherein the second screen plates are configured to prevent the airflow from entering the load ports.

It should be noted that the aspects of the present disclosure are not limited to those described above, and other aspects of the present disclosure will be apparent from the following description.

### BRIEF DESCRIPTION OF THE DRAWINGS

The above and other aspects and features of the present disclosure will become more apparent by describing in detail example embodiments thereof with reference to the attached drawings, in which:

FIG. 1 is a plan view illustrating an equipment front-end module (EFEM) according to one or more embodiments of the present disclosure;

FIG. 2 is a perspective view illustrating the interior of the EFEM according to one or more embodiments of the present disclosure;

FIGS. 3 and 4 are perspective views for explaining a first screen plate of FIG. 2;

FIG. 5 is a side view for explaining the first screen plate of FIG. 2;

FIG. 6 illustrates enlarged side views of areas P1 and P2 of FIG. 2;

FIG. 7 is an enlarged side view of area P3 of FIG. 2;

FIGS. 8 through 12 are drawings for explaining an EFEM according to various embodiments of the present disclosure;

FIG. 13 is a plan view for explaining substrate processing apparatus including an EFEM according to one or more embodiments of the present disclosure;

FIG. 14 is a view for explaining a first process chamber of FIG. 13; and

FIG. 15 is a view for explaining a second process chamber of FIG. 13.

### DETAILED DESCRIPTION

In this specification, although terms such as “first,” “second,” etc., are used to describe various elements or components, these elements or components are not limited by these terms. These terms are merely used to distinguish one element or component from another. Therefore, a first element or component mentioned below may be a second element or component within the technical spirit of the present disclosure.

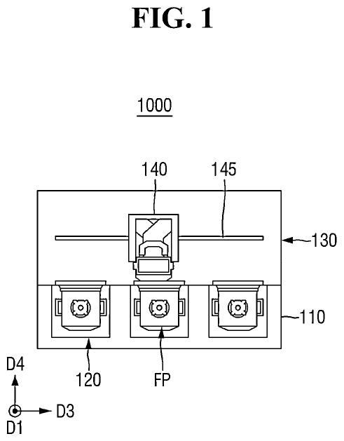

An equipment front-end module (EFEM) according to various embodiments of the present disclosure will hereinafter be described with reference to FIGS. 1 through 7.

FIG. 1 is a plan view illustrating an EFEM according to one or more embodiments of the present disclosure.

Referring to FIG. 1, an EFEM 1000 may include a body part 110, a plurality of load ports 120, and an index module 130.

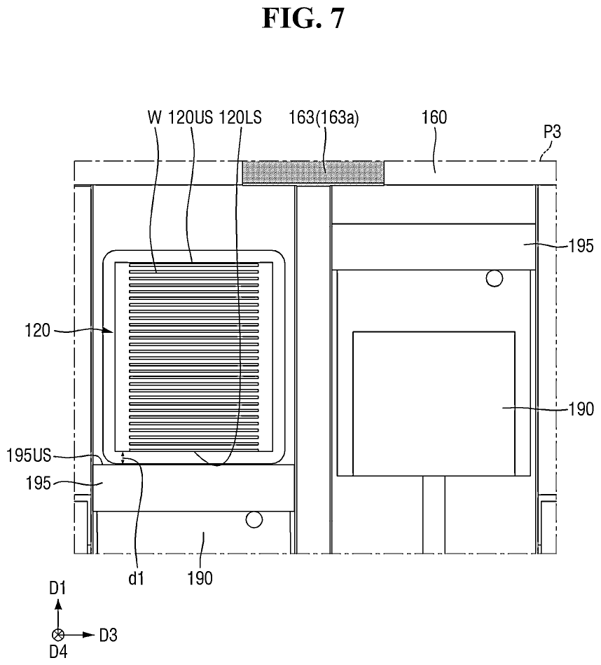

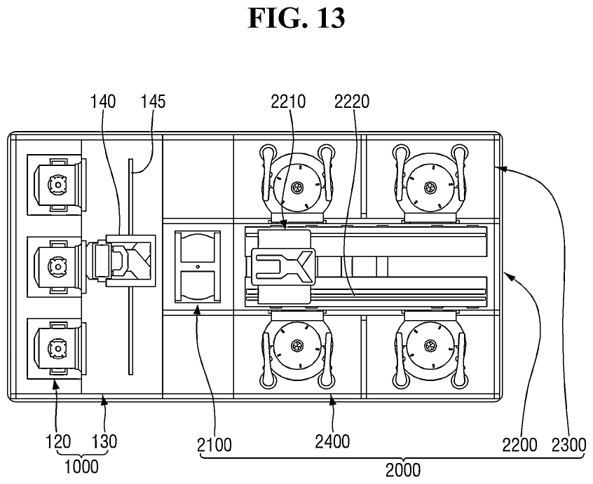

The index module 130 is disposed on one side of an array of the load ports 120. The index module 130 transfers wafers W (refer to FIG. 7), which are disposed in the load ports 120, to a first process chamber 2300 and a second process chamber 2400 (refer to FIG. 13). The load ports 120 provide spaces for front opening unified pods (FOUPs) FP, in which the wafers W are received. The index module 130 may include an index robot 140. The index robot 140 may retrieve wafers W, yet to be processed, from the FOUPs FP in the load ports 120 and may transfer them to a process module 2000 (refer to FIG. 13). Additionally, the index robot 140 may also load wafers W, that are already processed, from the first process chamber 2300 and the second process chamber 2400 into the FOUPs FP.

The load ports 120 may be arranged in series in a third direction D3. The load ports 120 may be spaced apart from one another in the third direction D3. FIG. 1 illustrates that there are provided three load ports 120, but embodiments of the present disclosure are not limited thereto.

A rail 145 may be disposed within the index module 130. The rail 145 may be installed on the bottom surface of the index module 130 or on the body part 110 of the EFEM 1000. The rail 145 may extend longitudinally in the third direction D3. The index robot 140 may move along the rail 145 in the third direction D3.

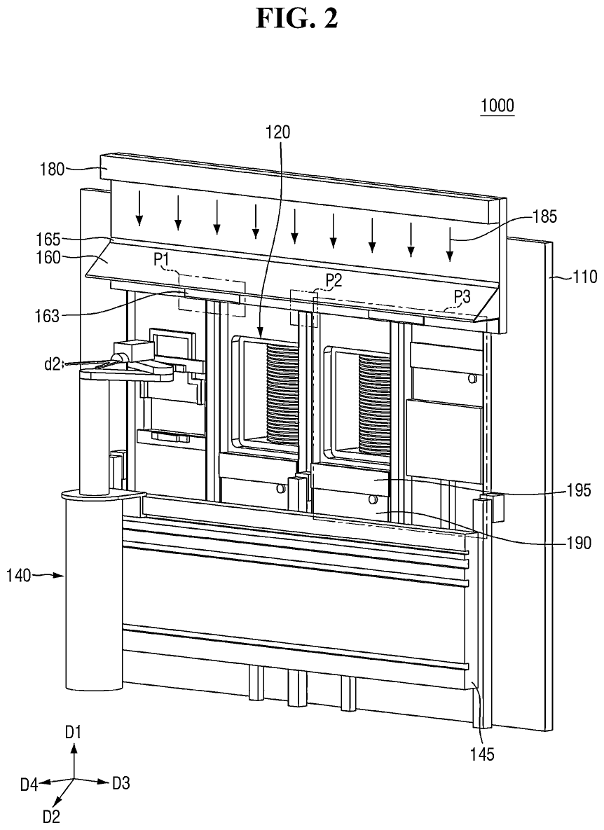

The EFEM 1000 will hereinafter be described in further detail with reference to FIGS. 2 through 7.

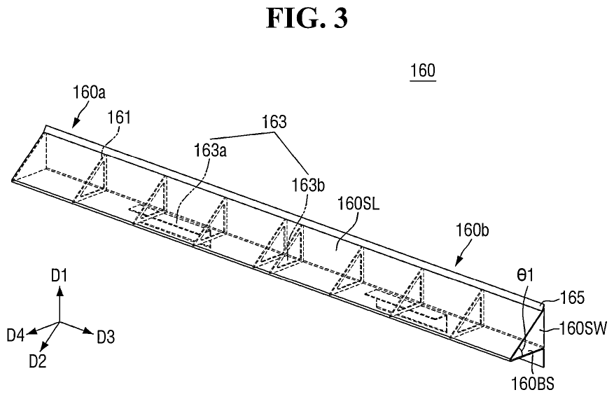

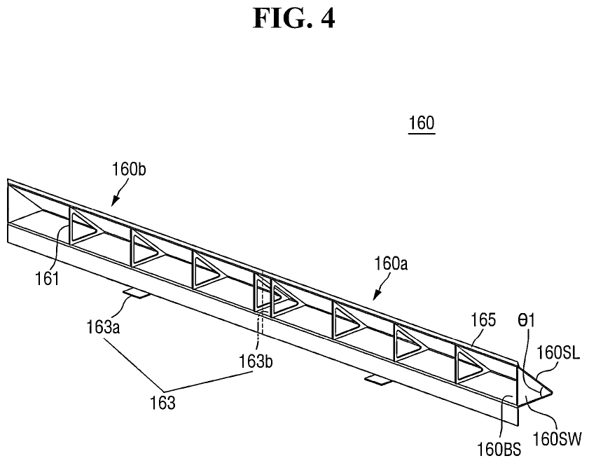

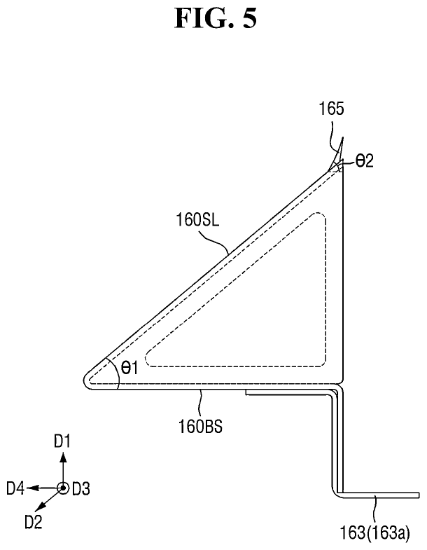

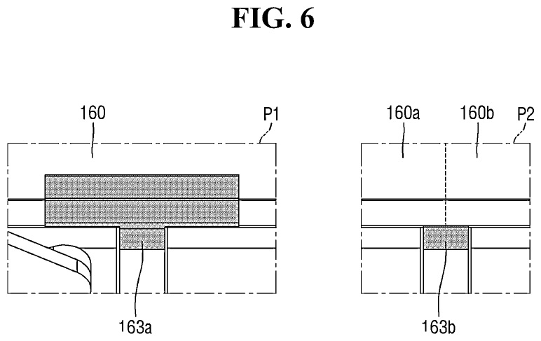

FIG. 2 is a perspective view illustrating the interior of the EFEM according to one or more embodiments of the present disclosure. FIGS. 3 and 4 are perspective of a first screen plate of FIG. 2. FIG. 5 is a side view of the first screen plate of FIG. 2. FIG. 6 illustrates enlarged side views of an area P1 and an area P2 of FIG. 2. FIG. 7 is an enlarged side view of an area P3 of FIG. 2.

Referring to FIGS. 2 through 7, the EFEM 1000 may include the body part 110, the load ports 120, the index robot 140, the rail 145, a first screen plate 160, a fan unit 180 (e.g., a fan), a sealing part 165 (e.g., a seal), brackets 163, doors 190, and second screen plates 195.

First, the body part 110 may be provided. The body part 110 may be an outer or inner wall of the EFEM 1000. Various components may be arranged in the body part 110, e.g., on an inner wall of the body part 110. The body part 110 may have a height in the first direction D1.

In this specification, the first direction D1, a third direction D3, and a fourth direction D4 may be substantially perpendicular to one another. The first direction D1, the third direction D3, and the fourth direction D4 may be z-, x-, and y-axis directions, respectively, but embodiments of the present disclosure are not limited thereto.

The load ports 120 may be installed in the body part 110. One or more load ports 120 may be disposed. FIG. 2 illustrates three load ports 120, but embodiments of the present disclosure are not limited thereto. The load ports 120 may be recessed in the fourth direction D4 from the inner wall of the body part 110. The FOUPs FPs may be disposed in the load ports 120. The FOUPs FPs may be containers storing multiple wafers W. In other words, the load ports 120 may be spaces that accommodate multiple wafers W.

The fan unit 180 may be disposed above the load ports 120. The fan unit 180 may be installed on the body part 110. The fan unit 180 may generate an airflow. The airflow may be provided downward, as indicated by an arrow 185. That is, the airflow may be provided in a direction opposite to the first direction D1. Specifically, the airflow may be provided from the fan unit 180, which is disposed at an upper part of the EFEM 1000, and may be directed from the top to the bottom of the EFEM 1000.

The first screen plate 160 may be attached to the body part 110. The first screen plate 160 may be disposed between the load ports 120 and the fan unit 180. The first screen plate 160 may change the direction of the airflow provided by the fan unit 180. Specifically, the first screen plate 160 may prevent the airflow from entering the load ports 120.

The first screen plate 160 may be elongated in the third direction D3. The first screen plate 160 may protrude in the fourth direction D4 from the inner wall of the body part 110. The first screen plate 160 may have a height in the first direction D1.

Referring to FIGS. 3 through 5, the first screen plate 160 may include a slant edge 160SL, sidewalls 160SW, and a bottom surface 160BS. The interior defined by the slant edge 160SL, the sidewalls 160SW, and the bottom surface 160BS of the first screen plate 160 may be an empty space.

The slant edge 160SL of the first screen plate 160 may extend in a second direction D2. The second direction D2 may be a direction between the direction opposite to the first direction D1 and the fourth direction D4. That is, the first screen plate 160 may be inclined. Since the first screen plate 160 is inclined, the first screen plate 160 can change the direction of an airflow. For example, the airflow may flow first in the direction opposite to the first direction D1 and then in the second direction D2. As the airflow flows in the second direction D2, the airflow can be prevented from entering the load ports 120.

In one or more embodiments, the angle between the bottom surface 160BS and the slant edge 160SL of the first screen plate 160 may be a first angle θ1. The first angle θ1 may range between 30° and 50°, inclusive.

If the first angle θ1 is less than 30°, the first screen plate 160 may protrude significantly in the fourth direction D4 from the inner wall of the body part 110, or the height, in the first direction D1, of the first screen plate 160 may increase. In this case, the first screen plate 160 may obstruct the path of the index robot 140.

Conversely, if the first angle θ1 is greater than 50°, the change in the direction of the airflow caused by the first screen plate 160 may be reduced. Consequently, some of the airflow may enter the load ports 120.

Since the first angle θ1 is between 30° and 50°, inclusive, the processing efficiency of substrate processing apparatus including the EFEM 1000 can be improved. According to embodiments, the first angle θ1 may be 40°, but embodiments of the present disclosure are not limited thereto.

The first screen plate 160 may include a plurality of frames 161. The frames 161 may be disposed in the empty space defined by the slant edge 160SL, the sidewalls 160SW, and the bottom surface 160BS. In other words, the frames 161 may have a triangular shape. The frames 161 may be spaced apart from one another in the third direction D3. The spacing between the frames 161 may be either uniform or vary.

For example, if the first screen plate 160 consists of a single sub-screen plate, the spacing between the frames 161 may be uniform. In another example, if the first screen plate 160 consists of multiple sub-screen plates, the spacing between the frames 161 may vary.

In one or more embodiments, the first screen plate 160 may include a first sub-screen plate 160a and a second sub-screen plate 160b. The first sub-screen plate 160a and the second sub-screen plate 160b may be arranged in series in the third direction D3. The spacing between the frames 161 in the empty space of the first sub-screen plate 160a is uniform. Similarly, the spacing between the frames 161 in the empty space of the second sub-screen plate 160b is also uniform.

However, a first spacing between the nearest frame in the empty space of the first sub-screen plate 160a to the second sub-screen plate 160b and the nearest frame in the empty space of the second sub-screen plate 160b to the first sub-screen plate 160a may differ from a second spacing between the frames 161 (e.g., of the first sub-screen plate 160a and/or of the second sub-screen plate 160b). For example, the first spacing may be smaller than the second spacing, but embodiments of the present disclosure are not limited thereto.

Brackets 163 may be used to attach the first screen plate 160 to the body part 110. At least one of the brackets 163 may be provided. Referring to FIG. 6, the brackets 163 may include first brackets 163a and a second bracket 163b.

The first brackets 163a and the second bracket 163b may have different shapes. The first brackets 163a may include horizontal parts and vertical parts. The second bracket 163b may include a horizontal part only.

The first brackets 163a may be used to attach the first screen plate 160 to the body part 110. For example, the first screen plate 160 and the body part 110 may be tightly coupled by screws passing through the vertical parts of the first brackets 163a. Parts of the first screen plate 160 may be interposed between the body part 110 and the first brackets 163a. Parts of the first screen plate 160, the body part 110, and the first brackets 163a may be fixed with the screws. One or more first brackets 163a may be provided. A plurality of first brackets 163a may be spaced apart from one another in the third direction D3. The number of the first brackets 163a may vary depending on the embodiment.

The second bracket 163b may be used to fix the first screen plate 160 in place. As previously described, the first screen plate 160 may include the first sub-screen plate 160a and the second sub-screen plate 160b. The bonding strength may be weak at the boundary between the first sub-screen plate 160a and the second sub-screen plate 160b. The second bracket 163b may be disposed at the boundary between the first sub-screen plate 160a and the second sub-screen plate 160b. The first sub-screen plate 160a and the second sub-screen plate 160b can be firmly fixed together by the second bracket 163b.

A sealing part 165 may be disposed above the first screen plate 160. Specifically, the sealing part 165 may be disposed where the first screen plate 160 and the body part 110 contact each other. By using the sealing part 165, the first screen plate 160 can be firmly secured to the body part 110. Moreover, by positioning the sealing part 165 between the first screen plate 160 and the body part 110, the intrusion of particles into the empty space of the first screen plate 160 can be prevented.

Referring to FIG. 5, the angle of the sealing part 165 relative to the bottom surface 160BS of the first screen plate 160 may be a second angle θ2. The second angle θ2 may be greater than the first angle θ1, but embodiments of the present disclosure are not limited thereto.

The doors 190 may open and close the entrances of the load ports 120. Referring to FIG. 7, the left load port 120 may have its entrance open by one of the doors 190 being in an open state, and the right load port 120 may have its entrance closed by another one of the doors 190 being in a closed state.

The doors 190 may be movable in the first direction D1. When the doors 190 move in the first direction D1, the entrances of the load ports 120 are closed. When the doors 190 move in the direction opposite of the first direction D1, the entrances of the load ports 120 are opened. When the entrances of the load ports 120 are closed, wafers W cannot be moved in and out of the load ports 120.

The second screen plates 195 may be attached to the doors 190. The second screen plates 195 may protrude from the upper surfaces of the doors 190 in the first direction D1. The second screen plates 195 may prevent an airflow from entering the load ports 120 when the load ports 120 are open. This airflow may be provided by the fan unit 180 and may also be generated as the index robot 140 moves along the rail 145. As the second screen plates 195 protrude from the upper surfaces of the doors 190, the airflow can be effectively prevented from entering the load ports 120.

The second screen plates 195 have upper surfaces 195US. The upper surfaces 195US of the second screen plates 195 may face the first screen plate 160. The upper surfaces 195US of the second screen plates 195 may be uppermost parts of the second screen plates 195.

The load ports 120 have upper surfaces 120US and lower surfaces 120LS. The upper surfaces 120US of the load ports 120 are closer than the lower surfaces 120LS of the load ports 120 to the first screen plate 160.

When the load ports 120 are open, the second screen plates 195 do not overlap with the entrances of the load port 120 in the fourth direction D4. When the load ports 120 are open, the level of the upper surfaces 195US of the second screen plates 195 are lower than the level of the lower surfaces 120LS of the load ports 120. In other words, relative to the bottom surface of the body part 110, the level of the upper surfaces 195US of the second screen plates 195 is lower than the level of the lower surfaces 120LS of the load ports 120.

The upper surfaces 195US of the second screen plates 195 may not be disposed on the same vertical level as a vertical level of the lower surfaces 120LS of the load ports 120. For example, the upper surfaces 195US of the second screen plates 195 may be spaced apart in the direction opposite to the first direction D1 from the lower surfaces 120LS of the load ports 120 by a first distance d1. The first distance d1 may be greater than a thickness d2 (refer to FIG. 2) of the robot arm of the index robot 140. When the load ports 120 are open, the robot arm of the index robot 140 may enter the load ports 120 to grasp the wafers W. Therefore, the upper surfaces 195US of the second screen plates 195 and the lower surfaces 120LS of the load ports 120 may be spaced apart at least by the minimum space required for the robot arm of the index robot 140 to enter the load ports 120. Thus, the first distance d1 may be greater than the thickness d2 of the robot arm of the index robot 140.

When the load ports 120 are closed, the level of the upper surfaces 195US of the second screen plates 195 may be lower than the level of a lowermost part of the first screen plate 160.

Referring back to FIG. 2, the first screen plate 160 may extend, in the third direction D3, such as to overlap an entirety of the load ports 120 in the first direction D1. In other words, the length, in the third direction D3, of the first screen plate 160 may be greater than the length, in the third direction D3, of the load ports 120. The length, in the third direction D3, of the load ports 120 may be the distance, in the third direction D3, between the outer walls of outermost ones of the load ports 120, but embodiments of the present disclosure are not limited thereto.

The index robot 140 may have a height in the first direction D1. The level of the index robot 140 may be lower than the level of the bottom surface 160BS of the first screen plate 160. The index robot 140 may be disposed below the bottom surface 160BS of the first screen plate 160 to grasp the wafers W within the load ports 120 while moving in the third direction D3.

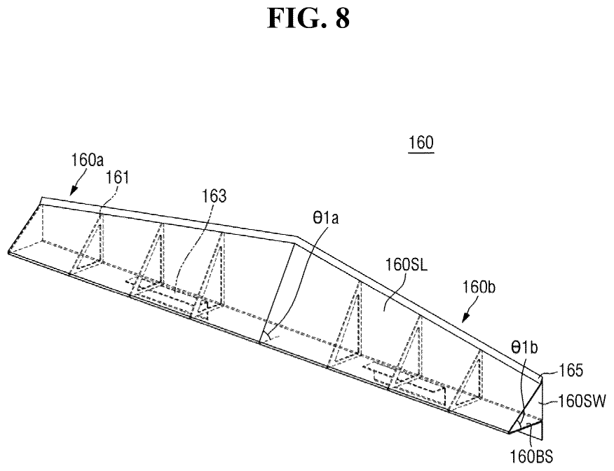

An EFEM according to various embodiments of the present disclosure will hereinafter be described with reference to FIGS. 8 through 12. For convenience, descriptions of content overlapping with what has been described above with reference to FIGS. 1 through 7 may be omitted.

Referring to FIG. 8, the angle between a bottom surface 160BS and a slant edge 160SL of a first screen plate 160 may not be uniform. For example, the angle between the bottom surface 160BS and the slant edge 160SL of the first screen plate 160 may increase in a direction from the edge to the center of the first screen plate 160.

For example, the angle between the bottom surface 160BS and the slant edge 160SL may be an edge angle θ1b at the edge of the first screen plate 160 and a center angle θla at the center of the first screen plate 160. The center angle θla may be greater than the edge angle θ1b.

Additionally, the height, in the first direction D1, of the first screen plate 160 may be less at the edge of the first screen plate 160 than at the center of the first screen plate 160 in the first direction D1. Consequently, an airflow generated by a fan unit 180 may flow from the center to the edge of the first screen plate 160.

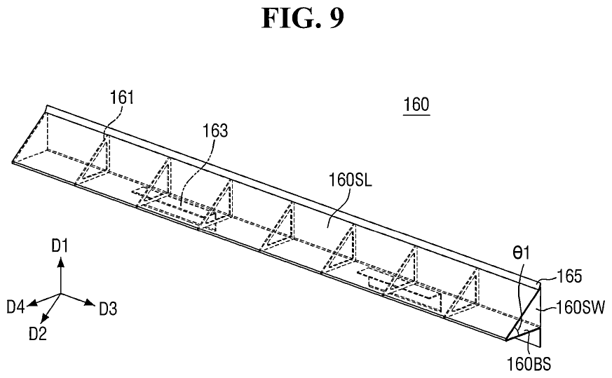

Referring to FIG. 9, the first screen plate 160 may include a single sub-screen plate. Therefore, frames 161 disposed in the empty space inside the first screen plate 160 may be spaced at intervals of the same distance. Moreover, brackets 163 may include first brackets 163a only, and may not include a second bracket 163b.

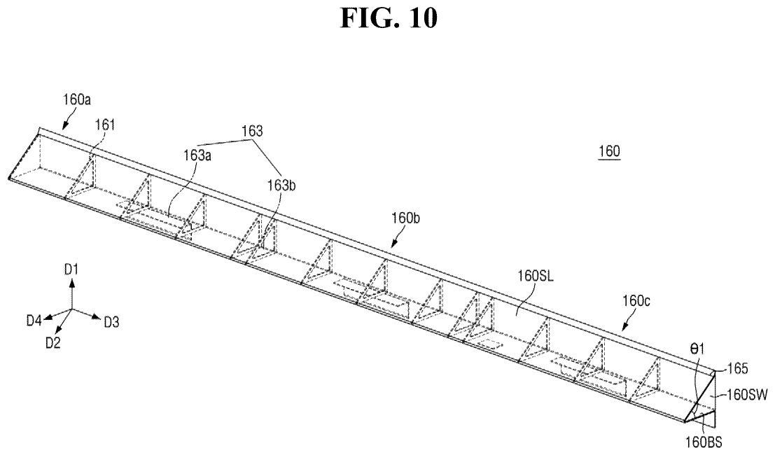

Alternatively, referring to FIG. 10, the first screen plate 160 may include three sub-screen plates. For example, the first screen plate 160 may include a first sub-screen plate 160a, a second sub-screen plate 160b, and a third sub-screen plate 160c. The first sub-screen plate 160a, the second sub-screen plate 160b, and the third sub-screen plate 160c may be arranged in series in the third direction D3. Specifically, the first sub-screen plate 160a, the second sub-screen plate 160b, and the third sub-screen plate 160c may be interconnected, and the second sub-screen plate 160b may be interposed between the first sub-screen plate 160a and the third sub-screen plate 160c.

The brackets 163 may include first brackets 163a and second brackets 163b. The second brackets 163b may be disposed between the first sub-screen plate 160a and the second sub-screen plate 160b, and may also be disposed between the second sub-screen plate 160b and the third sub-screen plate 160c. Due to the second brackets 163b, the first sub-screen plate 160a, the second sub-screen plate 160b, and the third sub-screen plate 160c can be firmly fixed together.

The first brackets 163a may be used to attach the first sub-screen plate 160a, the second sub-screen plate 160b, and the third sub-screen plate 160c to the body part 110 (refer to FIG. 2).

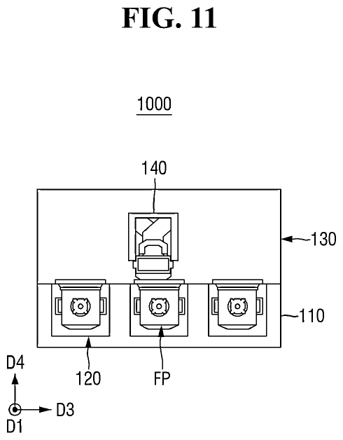

Referring to FIG. 11, an index module 130 may not include a rail 145. The index robot 140 may not move in the third direction D3 along the rail 145. The length of a robot arm of the index robot 140 may be adjusted to grasp and transport wafers disposed within a plurality of load ports 120.

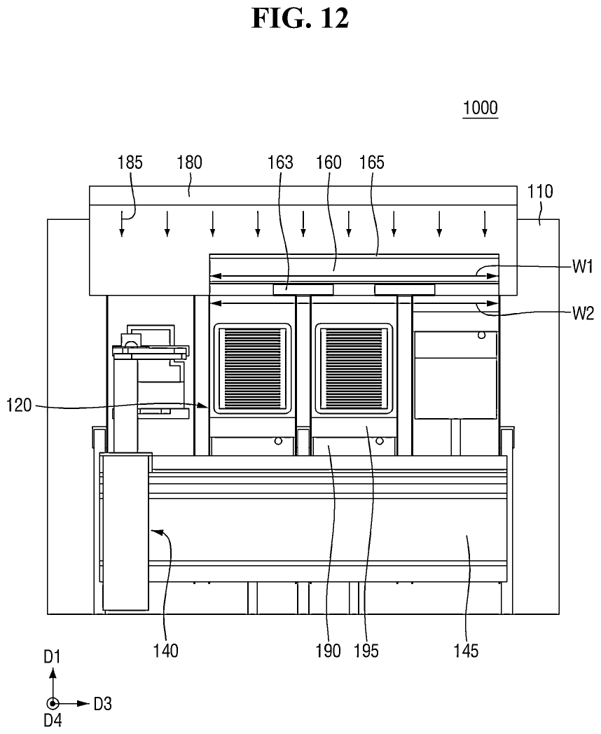

Referring to FIG. 12, a length W1, in the third direction D3, of the first screen plate 160 may be equal to a length W2, in the third direction D3, of the load ports 120. The length W2 of the load ports 120 W2 may be the distance, in the third direction D3, between the outer walls of outermost ones of the load ports 120.

Substrate processing apparatus including an EFEM according to some embodiments of the present disclosure will hereinafter be described with reference to FIGS. 13 through 15.

FIG. 13 is a plan view for explaining substrate processing apparatus including an EFEM according to one or more embodiments of the present disclosure.

Referring to FIG. 13, a substrate processing apparatus according to one or more embodiments of the present disclosure may include an EFEM 1000 and a process module 2000. The EFEM 1000 of FIG. 13 may be the EFEM 1000 of FIGS. 1 through 7.

The EFEM 1000 receives wafers from outside and transports the wafers to the process module 2000. The process module 2000 may perform at least one from among cleaning, deposition, etching, and ashing processes. The EFEM 1000 may include load ports 120 and an index module 130.

The load ports 120 may accommodate wafers. The wafers may be placed in containers within the load ports 120. The containers may be FOUPs. The containers may be transferred into and out of the load ports 120 via an overhead transfer (OHT). The index module 130 may transport wafers between the containers within the load ports 120 and the process module 2000.

The process module 2000 may be a module that actually performs processing. The process module 2000 may include a buffer chamber 2100, a transfer chamber 2200, a first process chamber 2300, and a second process chamber 2400. In one or more embodiments, each of the first process chamber 2300 and the second process chamber 2400 may be in the form of a tower including a plurality of process chambers, but embodiments of the present disclosure are not limited thereto.

The buffer chamber 2100 provides a space where wafers being transported between the EFEM 1000 and the process module 2000 can temporarily reside. The buffer chamber 2100 may include buffer slots where wafers are placed. A transfer robot 2210 of the transfer chamber 2200 may retrieve wafers from the buffer slots and transport the wafers to the first process chamber 2300 and the second process chamber 2400.

The transfer chamber 2200 transports wafers between the buffer chamber 2100 and process equipment (e.g., the first process chamber 2300 or the second process chamber 2400). The transfer chamber 2200 may include the transfer robot 2210 and a transfer rail 2220. The transfer robot 2210 may move along the transfer rail 2220 to transport wafers.

In one or more embodiments, the first process chamber 2300 and the second process chamber 2400 may be substrate processing devices. For example, at least one from among cleaning, deposition, etching, and ashing processes may be performed in the first process chamber 2300 and the second process chamber 2400.

The first process chamber 2300 may be disposed on one side of the transfer chamber 2200. The second process chamber 2400 may be disposed on the other side of the transfer chamber 2200. In other words, the first process chamber 2300 and the second process chamber 2400 may be disposed to face each other on different sides of the transfer chamber 2200.

However, the arrangement of the first process chamber 2300 and the second process chamber 2400 is not particularly limited and may vary depending on the footprint or process efficiency of the substrate processing apparatus according to other embodiments of the present disclosure.

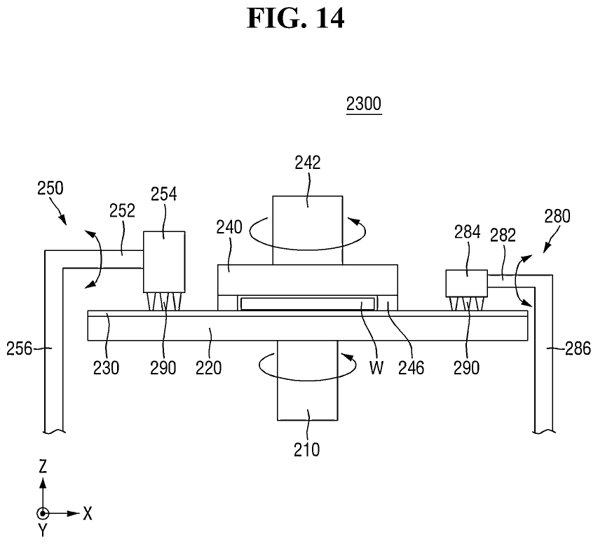

FIG. 14 is a drawing for explaining a first process chamber according to one or more embodiments of the present disclosure. FIG. 14 illustrates a chemical mechanical polishing (CMP) device, but embodiments of the present disclosure are not limited thereto. The first process chamber 2300 may be a chamber where an etching process is performed or where a deposition process is performed.

Referring to FIG. 14, the first process chamber 2300 may be a CMP device. The first process chamber 2300 may include a polishing platen 220 and a polishing pad 230, which is positioned on the polishing platen 220 and can be rotated. The polishing platen 220 is rotatable, and as the polishing platen 220 rotates, the polishing pad 230, which is mounted on the polishing platen 220, may also rotate the polishing pad 230. In FIG. 14, X- and Y-axis directions may be directions parallel to the surface of the polishing pad 230, and a Z-axis direction may be a direction perpendicular to the surface of the polishing pad 230.

The polishing platen 220 may be disc-shaped. The polishing platen 220 may be a rotating table that rotates in a particular direction, for example, a clockwise direction. The polishing pad 230 may be a hard polyurethane pad. The polishing pad 230 may be in close contact with a wafer W and may perform CMP on the wafer W.

The CMP device may include a polishing head 240, which is positioned on the polishing pad 230 and is capable of rotating with the wafer W mounted thereon. The polishing head 240 may move on an X-Y plane on the polishing pad 230. The polishing head 240 may perform CMP on the wafer W while being in close contact with the polishing pad 230.

The CMP device may include a polishing slurry supply device 250, which is positioned on the polishing pad 230 and supplies a polishing slurry. The polishing slurry supply device 250 may include a slurry arm 252, which performs a sweeping motion on the polishing pad 230, a slurry nozzle part 254, which is connected to the slurry arm 252 and also performs a sweeping motion while supplying a polishing slurry onto the polishing pad 230, and a slurry arm rotation shaft 256, which is connected to the slurry arm 252.

The slurry arm rotation shaft 256 may be a shaft that enables the sweeping motion of the slurry arm 252. The slurry arm rotation shaft 256 may be positioned on the outside of the polishing pad 230. The slurry arm 252 and the slurry nozzle part 254 may perform a sweeping motion on the X-Y plane on the polishing pad 230.

The slurry arm 252 and the slurry nozzle part 254 may perform a sweeping motions clockwise or counterclockwise on the X-Y plane. When the slurry arm 252 and the slurry nozzle part 254 perform a sweeping motion, the uniformity of the polishing slurry discharged onto the polishing pad 230 can be increased, reducing the amount of polishing slurry used during CMP.

The CMP device may include a polishing pad conditioning device 280, which is positioned on the polishing pad 230 for regulating the conditioning of the polishing pad 230. The polishing pad conditioning device 280 may include a conditioning arm 282, which performs a sweeping motion on the polishing pad 230, a conditioning disc 284, which is connected to the conditioning arm 282, performs a sweeping motion, and regulates the conditioning of the polishing pad 230, and a conditioning arm rotation shaft 286, which is connected to the conditioning arm 282.

The conditioning arm rotation shaft 286 may be a shaft that enables the sweeping motion of the conditioning arm 282. When the conditioning arm 282 and the conditioning disc 284 perform a sweeping motion, the conditioning arm 282 and the conditioning disc 284 can improve the conditioning of the polishing pad 230. The conditioning arm rotation shaft 286 may be positioned on the outside of the polishing pad 230.

The conditioning arm 282 and the conditioning disc 284 may perform a sweeping motion on the X-Y plane on the polishing pad 230. The conditioning arm 282 and the conditioning disc 284 may perform a sweeping motion either clockwise or counterclockwise on the X-Y plane.

The CMP device may include a platen center shaft 210, the polishing platen 220, which is mounted on the platen center shaft 210, and the polishing pad 230, which is mounted on the polishing platen 220. The platen center shaft 210 can rotate in a certain direction, for example, counterclockwise, and consequently, the polishing platen 220 and polishing pad 230 can also rotate.

The CMP device may include a polishing head 240 positioned opposite to the polishing pad 230 and capable of rotating in a certain direction, namely counterclockwise, by a polishing head center shaft 242. The polishing head 240 may include the wafer W held or mounted by a retainer ring 246.

The polishing head 240 may be pressed toward the polishing pad 230 by the polishing head center shaft 242. In other words, the polishing head 240 may press the wafer 244 via the polishing head center shaft 242.

The CMP device may include the polishing slurry supply device 250, which is positioned on one side of the polishing head 240 and supplies a polishing slurry 290. The polishing slurry supply device 250 may include the slurry arm 252, the slurry nozzle part 254, which is connected to the front end of the slurry arm 252, and the slurry arm rotation shaft 256, which is connected to the rear end of the slurry arm 252. The slurry arm 252 and the slurry nozzle part 254 may perform a sweeping motion around the slurry arm rotation shaft 256.

The wafer W mounted on the polishing head 240 may rotate while being in contact with the polishing pad 230, and may be planarized through CMP using the polishing slurry 290, supplied from the slurry nozzle part 254 of the polishing slurry supply device 250.

The CMP device may include the polishing pad conditioning device 280, which is positioned on one side of the polishing head 240 and regulates the conditioning of the polishing pad 230.

The polishing pad conditioning device 280 may include the conditioning arm 282, the conditioning disc 284, which is connected to the front end of the conditioning arm 282, and the conditioning arm rotation shaft 286, which is connected to the rear end of the conditioning arm 282. The conditioning arm 282 and the conditioning disc 284 may perform a sweeping motion around the conditioning arm rotation shaft 286. The conditioning disc 284 may be pressed toward the polishing pad 230 by a conditioner center shaft positioned on the conditioning disc 284.

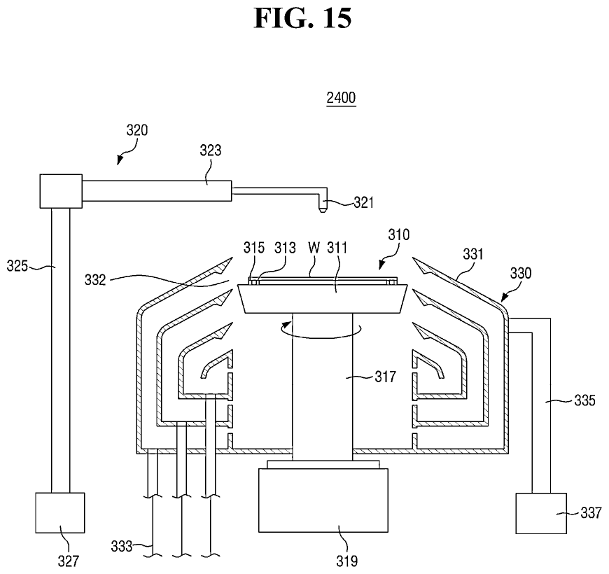

FIG. 15 is a drawing for explaining a second process chamber according to one or more embodiments of the present disclosure.

Referring to FIG. 15, the second process chamber 2400 may include a support unit 310, a nozzle structure 320, and a recovery unit 330.

The support unit 310 may support a wafer W. The support unit 310 may rotate the wafer W while the wafer W is supported. The support unit 310 may include a support plate 311, support pins 313, chuck pins 315, a rotation shaft 317, and a rotation driver 319.

The support plate 311 has an upper surface of the same shape as or a similar shape to the shape of the wafer W. The support pins 313 and the chuck pins 315 are formed on the upper surface of the support plate 311. The support pins 313 support the bottom of the wafer W. The chuck pins 315 may fix the wafer W.

The rotation shaft 317 is connected to the bottom of the support plate 311. The rotation shaft 317 receives a rotational force from the rotation driver 319 and thereby rotates the support plate 311. Consequently, the wafer W supported on the support plate 311 can be rotated. The chuck pins 315 prevent the wafer W from deviating from its correct position.

The nozzle structure 320 may supply a cleaning fluid to the wafer W. The nozzle structure 320 may include an arm 323 and a nozzle unit 321. The nozzle structure 320 may also include a nozzle shaft 325 (e.g., a nozzle axis) and a nozzle shaft driver 327.

The nozzle unit 321 sprays the cleaning fluid onto the wafer W. The nozzle unit 321 may be connected to the arm 323 and may be disposed to face the surface of the wafer W. The arm 323 is coupled to the nozzle shaft 325. The nozzle shaft 325 is provided to be elevatable and/or rotatable. The nozzle shaft driver 327 may elevate and/or rotate the nozzle shaft 325 and thereby adjust the position of the nozzle unit 321.

The recovery unit 330 recovers the cleaning fluid supplied to the wafer W. When the nozzle structure 320 supplies the cleaning fluid to the wafer W, the support unit 310 may rotate the wafer W to ensure the uniform distribution of the cleaning fluid over the entire area of the wafer W. As the wafer W rotates, the cleaning fluid is scattered from the wafer W. The scattered cleaning fluid may be recovered by the recovery unit 330.

The recovery unit 330 includes recovery tanks 331, recovery ports 332, recovery lines 333, a lifting bar 335, and a lifting driver 337. The recovery tanks 331 are provided in an annular ring shape surrounding the support plate 311. The height of the recovery tanks 331 increases away from the support plate 311. The recovery ports 332, into which the scattered cleaning fluid from the wafer W is introduced, are formed between the recovery tanks 331. The recovery lines 333 are formed on the bottom surface of the recovery tanks 331.

The lifting bar 335 is connected to at least one surface (e.g., bottom and/or side surfaces) of the recovery tanks 331. The lifting bar 335 receives power from the lifting driver 337 to lift up or bring down the recovery tanks 331. The lifting driver 337 may adjust the position of the recovery ports 332, into which the scattered cleaning fluid is introduced, by lifting up or bringing down the recovery tanks 331 via the lifting bar 335.

Non-limiting example embodiments of the present disclosure have been described above with reference to the accompanying drawings, but the present disclosure is not limited thereto and may be implemented in various different forms. It will be understood that embodiments of the present disclosure can be implemented in other specific forms without departing from the technical spirit of the present disclosure. Therefore, it should be understood that the example embodiments set forth herein are illustrative in all respects and not limiting.

What is claimed is:

1. An equipment front-end module (EFEM) comprising:
a body part;
load ports in the body part and configured to have loaded therein front opening unified pods (FOUPs) that are configured to store a plurality of wafers;
doors in the body part and configured to move in a first direction, and open and close entrances of the load ports;
a fan unit on the load ports and configured to provide an airflow in a direction opposite to the first direction;
a first screen plate between the fan unit and the load ports and attached to the body part, the first screen plate comprising a slant edge that extends in a second direction that intersects the first direction; and
second screen plates attached to the doors and that extend in the first direction from upper surfaces of the doors,
wherein the first screen plate is configured to change a direction of the airflow, and
wherein the second screen plates are configured to prevent the airflow from entering the load ports.

2. The EFEM of claim 1, wherein in a case that the doors open the entrances of the load ports, a level of uppermost parts of the second screen plates is lower than a level of lower surfaces of the load ports.

3. The EFEM of claim 1, wherein the first screen plate further comprises a bottom surface and sidewalls, the sidewalls being connected to the slant edge, and
wherein an interior of the first screen plate defined by the slant edge, the bottom surface, and the sidewalls is an empty space.

4. The EFEM of claim 3, further comprising:
a plurality of frames inside the first screen plate and supporting the slant edge and the bottom surface.

5. The EFEM of claim 4, wherein a spacing between the plurality of frames is uniform.

6. The EFEM of claim 1, wherein the first screen plate further comprises a bottom surface that is connected to the slant edge and extends in a third direction that intersects the first direction and the second direction, and
wherein an angle of the slant edge relative to the bottom surface of the first screen plate is in a range of 30° to 50°, inclusive.

7. The EFEM of claim 6, wherein the angle of the slant edge relative to the bottom surface is uniform along the third direction.

8. The EFEM of claim 6, wherein the angle of the slant edge relative to the bottom surface increases in a direction from an edge part of the first screen plate to a central part of the first screen plate.

9. The EFEM of claim 1, wherein the first screen plate comprise a first sub-screen plate and a second sub-screen plate that have a same size as each other, and
wherein the first sub-screen plate and the second sub-screen plate are connected in series in a third direction that intersects the first direction and the second direction.

10. The EFEM of claim 1, wherein the slant edge contacts the body part, and
wherein the EFEM further comprises a sealing part disposed where the slant edge and the body part contact each other.

11. The EFEM of claim 1, wherein a length of the first screen plate in a third direction that intersects the first direction and the second direction is greater than a length of the load ports in the third direction.

12. An equipment front-end module (EFEM) comprising:
a body part;
load ports in the body part and configured have loaded therein front opening unified pods (FOUPs) that are configured to store a plurality of wafers;
doors in the body part and configured to move in a first direction and open and close entrances of the load ports;
a fan unit on the load ports and configured to provide an airflow in a direction opposite to the first direction;
a first screen plate between the fan unit and the load ports and attached to the body part, the first screen plate comprising:
a slant edge that extends in a second direction that intersects the first direction;
a bottom surface that is connected to the slant edge and extends in a third direction that intersects the first direction and the second direction; and
sidewalls that are connected to the slant edge and the bottom surface;
second screen plates attached to the doors and extending in the first direction from upper surfaces of the doors; and
an index robot configured to grasp and transfer the plurality of wafers disposed in the load ports,
wherein an interior of the first screen plate defined by the slant edge, the bottom surface, and the sidewalls is an empty space, and
wherein a height from lower surfaces of the load ports to a bottom surface of the first screen plate is greater than a height from the lower surfaces of the load ports to an uppermost part of the index robot.

13. The EFEM of claim 12, wherein an angle of the slant edge relative to the bottom surface is in a range of 30° to 50°, inclusive.

14. The EFEM of claim 13, wherein the angle of the slant edge relative to the bottom surface is uniform along the third direction.

15. The EFEM of claim 13, wherein the angle of the slant edge relative to the bottom surface gradually increases from an edge part of the first screen plate to a central part of the first screen plate.

16. The EFEM of claim 12, wherein the index robot comprises a robot arm that is configured to directly grasp the plurality of wafers, and
wherein in a case that the doors open entrances of the load ports, a length, in the first direction, from uppermost parts of the second screen plates to the lower surfaces of the load ports is greater than a thickness of the robot arm.

17. The EFEM of claim 12, wherein the first screen plate comprises a first sub-screen plate and a second sub-screen plate having a same size as each other, and
the first sub-screen plate and the second sub-screen plate are connected in series in the third direction.

18. The EFEM of claim 12, wherein the EFEM further comprises a rail that extends in the third direction, and the index robot is movable along the rail.

19. A substrate processing apparatus comprising:
an equipment front-end module (EFEM) that is configured to accommodate therein front opening unified pods (FOUPs) that store wafers;
a process chamber connected to the EFEM and configured to perform a semiconductor process on the wafers; and
a cleaning chamber configured to perform a cleaning process on the wafers that have been subjected to the semiconductor process,
wherein the EFEM comprises:
a body part;
load ports in the body part and configured to have the FOUPs loaded therein,
doors in the body part and configured to move in a first direction and open and close entrances of the load ports;
a fan unit on the load ports and configured to provide an airflow in a direction opposite to the first direction,
a first screen plate between the fan unit and the load ports, and attached to the body part, the first screen plate comprising a slant edge extending in a second direction that intersects the first direction, and
second screen plates attached to the doors and extending in the first direction from upper surfaces of the doors,
wherein the first screen plate is configured to change a direction of the airflow, and
wherein the second screen plates are configured to prevent the airflow from entering the load ports.

20. The substrate processing apparatus of claim 19, wherein the first screen plate further comprises a bottom surface connected to the slant edge and extending in a third direction that intersects the first direction and the second direction, and
wherein an angle of the slant edge relative to the bottom surface of the first screen plate is in a range of 30° to 50°, inclusive.
